(19) United States
(12) Patent Application Publication
(10) Pub. No.: US 2025/0138420 A1
(43) Pub. Date: May 1, 2025

(54) ENHANCED EUV PHOTORESISTS AND METHODS OF THEIR USE

(71) Applicants: Alex Phillip Graham Robinson, Northfield, Birmingham (GB); Alexandra McClelland, Worcestershire (GB); Fernanda Meloni, Birmingham (GB); Van Huy Nguyen, Birmingham (GB); Gregory O'Callaghan, Hagley (GB); Edward Jackson, Franklin, MA (US)

(72) Inventors: Alex Phillip Graham Robinson, Northfield, Birmingham (GB); Alexandra McClelland, Worcestershire (GB); Fernanda Meloni, Birmingham (GB); Van Huy Nguyen, Birmingham (GB); Gregory O'Callaghan, Hagley (GB); Edward Jackson, Franklin, MA (US)

(73) Assignee: Irresistible Materials LTD, Birmingham, EN (GB)

(21) Appl. No.: 18/867,700

(22) PCT Filed: May 22, 2023
(86) PCT No.: PCT/IB2023/000323

§ 371 Date: Dec. 2, 2024

(51) Int. Cl. G03F 7/027; G03F 7/004

(52) U.S. Cl. CPC G03F 7/027; G03F 7/0045; G03F 7/0048

(57) ABSTRACT

Disclosed and claimed herein are novel non-polymeric, aromatic-based core molecules containing oxygen bearing, acid or base reactive, crosslinking functionalities with improved sensitivity (photospeed), resolution (Line Width Roughness) or both when formulated in EUV photoresists. Also disclosed are formulations and processes made from the molecules disclosed.

### FIELD OF INVENTION

The present application for patent discloses non-polymeric, aromatic-based core molecules containing oxygen bearing, acid or base reactive, crosslinking functionalities with improved sensitivity (photospeed), resolution (Line Width Roughness) or both when formulated in EUV photoresists. Also disclosed are formulations made from the molecules disclosed.

### BACKGROUND

Extreme ultraviolet lithography (EUVL) is one of the leading technology options to replace optical lithography for volume semiconductor manufacturing at feature sizes <20 nm. The extremely short wavelength (13.4 nm) is a key enabling factor for high resolution required at multiple technology generations. In addition, the overall system concept—scanning exposure, projection optics, mask format, and resist technology—is quite similar to that used for current optical technologies. Like previous lithography generations, EUVL consists of resist technology, exposure tool technology, and mask technology. The key challenges are EUV source power and throughput. Any improvement in EUV power source will directly impact the currently strict resist sensitivity specification. Indeed, a major issue in EUVL imaging is resist sensitivity, the lower the sensitivity, the greater the source power that is needed or the longer the exposure time that is required to fully expose the resist. The lower the power levels, the more noise affects the line width roughness (LWR) and line-edge growth in negative tone resists or line edge recession in positive tone resists of the printed lines. As features of the resist dimensions are reduced to the wavelengths of the imaging radiation, obtaining patterns that have acceptable LWR is very difficult.

Various attempts have been made to alter the make-up of EUV photoresist compositions to improve performance of functional properties. Electronic device manufacturers continually seek increased resolution of a patterned photoresist image. It would be desirable to have new photoresist compositions that could provide enhanced imaging capabilities, including new photoresist compositions useful for EUVL.

As is well known, the manufacturing process of various kinds of electronic or semiconductor devices such as ICs, LSis and the like involves fine patterning of a resist layer on the surface of a substrate material such as, for example, a semiconductor silicon wafer. This fine patterning process has traditionally been conducted by the photolithographic method in which the substrate surface is uniformly coated with a positive or negative tone photosensitive composition to form a thin layer and selectively irradiating with actinic rays (such as ultraviolet (UV), deep UV, vacuum UV, extreme UV, x-rays, electron beams and ion beams) via a transmission or reflecting mask followed by a development treatment to selectively dissolve away the coated photosensitive layer in the areas exposed or unexposed, respectively, to the actinic rays leaving a patterned resist layer on the substrate surface. The patterned resist layer, thus obtained, may be utilized as a mask in the subsequent treatment on the substrate surface such as etching. The fabrication of structure with dimensions on the order of nanometers is an area of considerable interest since it enables the realization of electronic and optical devices which exploit novel phenomena such as quantum confinement effects and also allows greater component packing density. As a result, the resist pattern is required to have an ever-increasing fineness which can be accomplished by using actinic rays having a shorter wavelength than the conventional ultraviolet light. Accordingly, it is now the case that, in place of the conventional ultraviolet light, electron beams (e-beams), excimer laser beams, EUV, BEUV and X-rays are used as the short wavelength actinic rays. Needless to say, the minimum size obtainable is, in part, determined by the performance of the resist material and, in part, the wavelength of the actinic rays. Various materials have been proposed as suitable resist materials. For example, in the case of negative tone resists based on polymer crosslinking, there is an inherent resolution limit of about IO nm, which is the approximate radius of a single polymer molecule.

It is also known to apply a technique called “chemical amplification” to resist materials. A chemically amplified resist material is generally a multi-component formulation in which there is a matrix material, frequently a main polymeric component, such as a polyhydroxystyrene (PROST) resin protected by acid labile groups and a photo acid generator (PAG), as well as one or more additional components which impart desired properties to the resist. The matrix material contributes toward properties such as etching resistance and mechanical stability. By definition, the chemical amplification occurs through a catalytic process involving the PAG, which results in a single irradiation event causing the transformation of multiple resist molecules. The acid produced by the PAG reacts catalytically with the polymer to cause it to lose a functional group or, alternatively, cause a crosslinking event. The speed of the reaction can be driven, for example, by heating the resist film. In this way the sensitivity of the material to actinic radiation is greatly increased, as small numbers of irradiation events give rise to a large number of solubility changing events. As noted above, chemically amplified resists may be either positive or negative working.

Not to be held to theory, it is believed that improvements in sensitivity leads to improved structural integrity of the photo pattern of the resist. This may be due to the reduction in stray, diffracted or diffused radiation. Also in systems where crosslinking and ultimately photochemically enhanced polymerization is the key method of creating a photopatterns, it is believed that controlling the crosslinking and/or polymerization improves the accuracy of the pattern desired, such as elimination or reducing, such unwanted issues such as LWR (Line Width Roughness), line growth and line sharpening.

It is also generally accepted that in negative photoresist systems based on curing mechanism that depend on crosslinking and/or polymerization reactions, the reactions occur with little control due to chain reactions that harden the resist. In typical photoresists under exposure will undercure the photo pattern while over exposure will cause broadening of the photo pattern. In almost all negative working resist processes, post exposure baking (PEB) is required to harden the resist to a point where it will withstand the development process including high pH developers, as well as solvent and semi-aqueous developer. Maintaining the desired photopattern is difficult when the exposed photoresist is exposed to the high temperatures of standard resist processes.

The patent literature is rife with photoresist formulations that include epoxy materials as crosslinkers used in acid catalyzed curing processes. The patent literature describes a plethora of compounds useful in the resists, indicating that each one is as good as the other, while only supporting a very small number in experiments as well as process results. Many of the materials are disclosed in a listing of all possible variations but without supporting data. The resist pattern literature does not describe any novel, unique or improvements in crosslinkers, especially crosslinking solutions to improving the resist photospeed and/or reduction of LWR. We have undertaken an in-depth study to determine the validity that all the crosslinking compounds are equivalent to provide sensitivity and fine-line photo patterns and have surprisingly found several unique, novel crosslinkers do, in fact, provide major improvements in the generation of photopatterns created with EUV actinic radiation.

The current application for patent discloses and claims novel crosslinkers that are based on tris(triphenyl)methane as the core functionality as well as novel crosslinkers that are based on 1,4-Bis-(diphenylmethyl) benzene as the core functionality. The unexpected findings disclosed in this application are not limited to tris(triphenyl)methane or 1,4-Bis-(diphenylmethyl) benzene and can be expected to apply to other aromatic systems that function as crosslinkers, including, for example polynuclear aromatic compounds, aromatic heterocycles, bi-phenyl compounds, mono-aromatic compounds and the like.

It is also proposed that these unique and novel crosslinker are useful in convention photoresist exposure processes, such as, for example, 365 nm, 248 nm and 193 nm exposure schemes.

### DESCRIPTION OF THE FIGURES

FIG. 1 shows the molecular structure of the control compound used in this disclosure as well as the molecular structure of the novel crosslinkers I through 5 presented in the current disclosure.

FIG. 2 shows the molecular structures of novel crosslinkers 6 through 11 presented in the current disclosure.

FIG. 3 shows the molecular structures of novel crosslinkers 12 through 16 presented in the current disclosure.

FIG. 4 shows the molecular structures of novel crosslinkers 17 through 21 presented in the current disclosure.

FIG. 5 shows the molecular structure of novel crosslinkers 22 showing ortho, para, para substitutions of the oxygen groups on the phenyl groups.

FIGS. 6-9 shows SEMs images of 22 nm lines and spaces resulting from processing photoresists containing the novel crosslinkers that are presented in the current disclosure.

### DETAILED DESCRIPTION OF THE DISCLOSURE

In a first embodiment, disclosed and claimed herein are acid or base sensitive crosslinkers. comprising a core tris(4-hydroxyphenyl)methane group having the structure I:

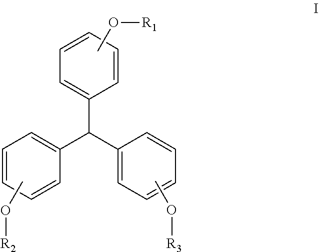

wherein -0-RI through -0-R3 positioned individually ortho, meta, or para to the methane atom and RI through R3 are the same or different and are comprised of at least one epoxy-ether crosslinking functionalities, cycloepoxy-ether crosslinking functionalities and/or oxetane-ether crosslinking functionalities.

In a second embodiment, disclosed and claimed herein are acid or base sensitive crosslinkers comprising a core I,4-(bis-4′-hydroxydiphenylmethyl) benzene core having the structure II:

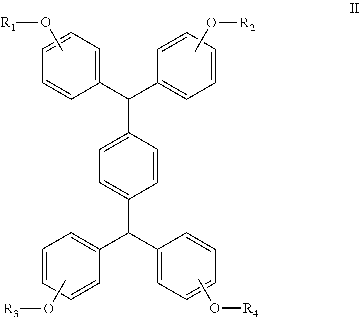

wherein -0-RI through -0-R4 are positioned individually ortho, meta, or para to the methane atoms and RI through R4 are the same or different and are comprised of at least one epoxy-ether crosslinking functionalities, cycloepoxy-ether crosslinking functionalities and/or oxetane-ether crosslinking functionalities.

In a third embodiment, disclosed and claimed herein are the acid or base sensitive crosslinkers of any of the above embodiments, wherein RI-R4 may be the same or different, comprising glycidyl ethers, I,2-epoxy 4-butyl ethers, I,2-epoxy cyclohexane-4-methyl ethers or oxetane ether groups.

In a fourth embodiment, disclosed and claimed herein are the acid or base sensitive crosslinkers of any of the above embodiments, wherein at least one of the hydrogens on at least one of the hydroxyphenyl groups are substituted with iodide, fluoride or fluoride-containing groups, or combinations thereof.

In a fifth embodiment, disclosed and claimed herein are photosensitive compositions comprising at least one epoxy ether having a structure chosen from I or II below:

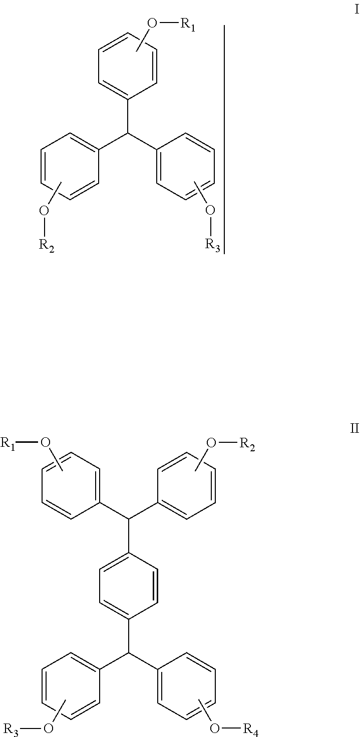

at least one photoacid or photobase generator; optionally a zwitterionic component; and at least one solvent, wherein -0-RI through -0-R4 are positioned individually ortho, meta, or para to the methane atoms and RI through R4 are the same or different comprising epoxy-ether crosslinking functionalities and/or oxetane-ether crosslinking functionalities.

In a sixth embodiment, disclosed and claimed herein are the compositions of the above embodiments, wherein RI-R4 may be the same or different comprising glycidyl ethers, 1,2-epoxy 4-butyl ethers, 1,2-epoxy cyclohexane-4-methyl ethers or oxetane ether groups.

In a seventh embodiment, disclosed and claimed herein are the compositions of the above embodiments wherein any of the phenyl groups are substituted with iodides, fluorides or fluoride-containing groups, or combinations thereof.

In an eighth embodiment, disclosed and claimed herein are the compositions of the above embodiments further comprising a nucleophilic quencher, wherein the nucleophilic quencher is triphenylsulphonium triflate or triphenylsulphonium tosylate.

In a ninth embodiment, disclosed and claimed herein are composition of the above embodiments wherein the at least one photoacid generator is chosen from a sulfonium salt, an iodonium salt, a sulfone imide, a halogen-containing compound, a sulfone compound, an ester sulfonate compound, a diazomethane compound, a dicarboxyimidyl sulfonic acid ester, an ylideneaminooxy sulfonic acid ester, a sulfanyl-diazomethane or a mixture thereof and wherein the at least one solvent comprises an ester, an ether, an ether-ester, a ketone, a cyclic ketone, a halogenate solvent, an alkyl-aryl ether, an alcohol or a combination thereof.

As used herein, the terms ortho, meta and para are positioned on the core aromatic rings relative to the methane carbo to which the aromatic groups are bonded.

As used herein, the conjunction “and” is intended to be inclusive and the conjunction “or” is not intended to be exclusive unless otherwise indicated. For example, the phrase “or, alternatively” is intended to be exclusive.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

As used herein the term PHOTOSPEED means the EUV dosage required to obtain 22 nm lines when processed through the Test of Formulations described below.

As used herein the term “blend” refers to the mixing of at least two of the crosslinkers which may differ in the basic structure, substituents and/or isomers.

The novel crosslinkers of the current disclosure contain cores of tris(4-hydroxyphenyl)methane or cores of 1,4-(bis-4′-hydroxydiphenylmethyl)benzene. The oxygen substituents are positioned on the three core phenyl groups on Structure I ortho, meta or para to the methyl atom or atoms of the core structure. The three oxygen substituents may be positioned differently in that one oxygen substituent may be para while another oxygen substituent may be meta and the third oxygen substituent may be ortho, meta or para. The oxygen substituents are positioned on four of the core phenyl groups which are bonded to the central core phenyl group on Structure II ortho, meta or para to the methyl atom or atoms of the core structure. The oxygen substituents may be positioned differently in that one oxygen substituent may be para while another oxygen substituent may be meta and the third oxygen substituent may be ortho, meta or para.

The zwitterionic component of the photosensitive compositions of the current disclosure can be:

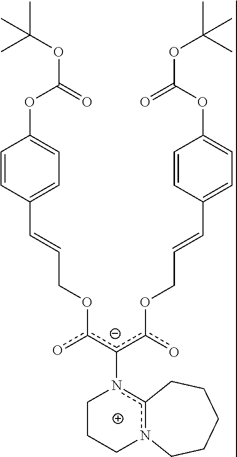

### EXPERIMENTAL

### Synthesis of Materials

The following is the general procedure for synthesizing representative novel crosslinkers of the current disclosure:
A) Condensation of Chosen Aldehyde with Phenol to Create the Triphenylmethyl Core:

Under an argon atmosphere, the aldehyde (1.00 equiv.), phenol (4.0 equiv.), PTSA (20 mol ¾) and zinc chloride (20 mol ¾) were placed into an appropriately sized flask. The reaction mixture was heated to 50° C. and stirred overnight. Water (25 mL) was added, and the reaction mixture extracted with EtOAc (3×25 mL). The combined organic fractions were washed with water (3×15 mL) and brine (15 mL), dried over anhydrous magnesium sulphate, filtered, and concentrated under reduced pressure to afford a crude residue that was purified by automated flash column chromatography (0-100% Hx/EtOAc).

### B) Synthesis of Chosen Epoxide:

Under an argon atmosphere, the triphenylmethyl core from A) (1.0 equiv.) was dissolved in epichlorohydrin (30.0 equiv.). Tetraethylammonium iodide (20 mol ¾) was added and the mixture heated to 80° C. overnight. A solution of NaOH in water (50%, w/w, 4.5 equiv.) was added and the reaction stirred for further 3 h. Once cooled to room temperature, the mixture was stirred through cotton wool, and the filtrate collected. Water (25 mL) was added, and the reaction mixture extracted with EtOAc (2×25 mL). The combined organic fractions were washed with water (3×15 mL) and brine (15 mL), dried over anhydrous MgSQ4, filtered, and concentrated under reduced pressure to afford a crude residue that was purified by automated flash column chromatography (0-100% Hx/EtOAc).

C) Dealkylation Reaction (when Required)

Under an argon atmosphere, boron tribromide (1.0 Min heptane, 4.5 equiv.) was added dropwise to a cooled solution of the chosen triphenylmethane core (1.0 equiv.) in anhydrous dichloromethane (0.2 M) at O ° C. The resulting solution was allowed to warm to room temperature and stirred overnight. Water (25 mL) was added, and the reaction mixture extracted with EtOAc (3×25 mL). The combined organic fractions were washed with water (3×15 mL) and brine (15 mL), dried over anhydrous MgSQ4, filtered, and concentrated under reduced pressure to afford a crude residue that was purified by automated flash column chromatography (0-100% Hx/EtOAc).

D) Iodination (when Required)

Under an argon atmosphere, the chosen triphenylmethane core (1.0 equiv.), NaOH (3.3 equiv.) and KI (3.3 equiv.) were dissolved in a solution of water/ethanol (75:25, v/v). The solution was cooled to O ° C., and h (3.3 equiv.) was added. The resulting mixture was covered with aluminium foil and allowed to warm to room temperature and stirred overnight. A solution of HCl in water (4.0 M, 40 mL) was added, and the mixture extracted with EtOAc (1×400 mL). The combined organic fractions were washed with a saturated solution of sodium thiosulfate (1×100 mL), brine (1×100 mL), dried over anhydrous MgSQ4, filtered, and concentrated under reduced pressure to afford a crude product that was purified by automated flash column chromatography (0-100% Hx/EtOAc

### Synthesis of Compound 19

### Synthesis of 4,4′-((4-ethoxyphenyl)methylene)diphenol 7

Compound prepared from 4-ethoxybenzaldehyde, following General Procedures Condensation, on a 13.35 mmol scale. 7 was afforded as an off-white solid in 58% yield (2.470 g; 58%).

### Synthesis of 4,4′-((4-ethoxyphenyl)methylene)bis(2,6-diiodophenol) 8

Adapted from a literature procedure.² 4,4′-((4-Ethoxyphenyl)methylene)diphenol 7 (2.470 g, 7.71 mmol) was dissolved in a solution of KOH (3.24 g, 57.82 mmol) in MeOH (39.0 mL). To this solution, h (7.830 g, 30.84 mmol) was added in one portion, and the reaction mixture stirred, under an argon protection, for ca. 10 min. A solution of HCl in water (4.0 M, 20 mL) was added until pH 4-5 was reached, hence the mixture extracted with EtOAc (3×25 mL). The combined organic fractions were washed with brine (25 mL), dried over anhydrous magnesium sulphate, filtered, and concentrated under reduced pressure to afford a crude product that was purified by automated flash column chromatography (0-100% Hx/EtOAc). The title compound was obtained as a dark solid (2.80 g; 44%).

### Synthesis of 4,4′-((4-hydroxyphenyl)methylene)bis(2,6-diiodophenol) 9

Compound prepared from 8 following General Procedures Dealkylation, on a 2.38 mmol scale. 9 was afforded as a pale-yellow solid (1.80 g; 95

### Synthesis of ((((((4-(oxiran-2-ylmethoxy)phenyl)methylene)bis(2,6-diiodo-4,1-phenylene))bis(oxy))bis(methylene))bis(oxetane-3,3-diyl))dimethanol

9 (1.70 g, 2.14 mmol) was dissolved in MeCN (7.1 mL) and to the resulting solution K2CO3 (0.82 g, 5.99 mmol) was added, followed by (3-(bromomethyl)oxetan-3-yl)methanol (1.07 g, 5.88 mmol). The mixture was stirred at 60° C. overnight, at which point another portion of potassium carbonate was added (0.41 g, 2.99 mmol), followed by epichlorohydrin (0.24 g, 2.57 mmol). After additional 16 h, water was added (10 mL) and the mixture extracted with EtOAc (3×25 mL). The combined organic fractions were washed with brine (25 mL), dried over anhydrous MgSQ4, filtered, and concentrated under reduced pressure. The obtained crude residue was purified by automated flash column chromatography (0-100% Hx/EtOAc). CL 2134 was afforded as a white solid (0.20 g; 9%).

### Synthesis of Compound 5

### Synthesis of 4,4′-((3-fluoro-4-methoxyphenyl)methylene)diphenol 15

Under nitrogen a mixture of 2-fluoro-p-anisaldehyde (4.00 g; 25.97 mmol), phenol (12.21 g; 129.87 mmol), ZnCh (0.32 g; 2.34 mmol) and PTSA (0.49 g; 2.6 mmol) were stirred at room temperature for 1 h after which a viscous slurry had formed. This was heated to 45° C. and left for 24 h. The reaction was cooled to room temperature. Ethyl acetate added (40 mL) and washed with water (2×10 mL). The organic phase was dried over MgSQ4 and evaporated to dryness in vacuo. The solid was further purified by column chromatography (silica; 80% hexane: 20% ethyl acetate) to afford 15 as a light yellow solid (5.90 g; 65%).

### Synthesis of 4,4′-((3-fluoro-4-methoxyphenyl)methylene)bis(2,6-diiodophenol) 16

Under nitrogen a solution of 15 (0.70 g; 2.16 mmol), NaOH (0.52 g; 12.96 mmol) and KI (1.98 g; 11.88 mmol) in water/ethanol (1:1, 50 mL) was cooled to O ° C. Iodine (3.02 g; 11.88 mmol) was added and the reaction was covered in foil and left to warm to room temperature. After 24 h HCl (6 M; 10 mL) was added. The precipitate was filtered, washed with water (3×20 mL), followed by hexane (10 mL). The precipitate was further purified by column chromatography (silica; 60% n-hexane: 40% ethyl acetate) to afford 16 as a white solid (0.90 g; 50%).

### Synthesis of 4,4′-((3-fluoro-4-hydroxyphenyl)methylene)bis(2,6-diiodophenol) 17

Under nitrogen a solution of 16 (0.33 g; 0.40 mmol) in degassed dichloromethane (5 mL) was cooled to −78° C. BBr3 (IM in dichloromethane; 1.32 mL) was added over a period of 5 minutes. The solution was left to warm to room temperature. After 20 h the reaction was quenched with ice (3 g). After the ice had melted, ethyl acetate (20 mL) was added. The mixture was washed with water (10 mL), followed by brine (10 mL) and then dried using MgSQ4_The organic phase was evaporated to dryness in vacuo to afford 17 as a white solid (0.27 g; 83%). No further purification was necessary. ¹HNMR: 413FOHF1 otter 10/12/20

### Synthesis of 2,2′-(((((3-fluoro-4-(oxiran-2-ylmethoxy)phenyl)methylene)bis(2,6-diiodo-4,1-phenylene))bis(oxy))bis(methylene))bis(oxirane)

Under nitrogen a solution of 17 (170 mg; 0.21 mmol), tetraethylammonium iodide (20 mg, 0.06 mmol) in epichlorohydrin (5 mL) was heated and held at 80° C. for 20 h. Sodium hydroxide (50% w/w in water; 0.94 mmol) was added to the reaction and it was left for a further 3 h. The reaction was cooled to room temperature and then gravity filtered. The precipitate was washed with ethyl acetate (2×10 mL). The washes were combined with the filtrate. The filtrate was washed with water (3×20 mL). dried over MgSQ4 and evaporated to dryness in vacuo. The solid was further purified by recrystallisation using ethyl acetate:hexane (1:5), and column chromatography (silica; 30% n-hexane: 70% ethyl acetate) to afford compound 5 as a white solid (30 mg; 15

### Synthesis of a Representative Novel Compound of the Current Disclosure

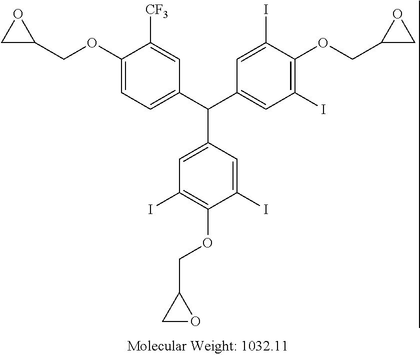 [SMILES: FC(F)(F)c1cc(C(c2cc(I)c(OCC3CO3)c(I)c2)c2cc(I)c(OCC3CO3)c(I)c2)ccc1OCC1CO1]

### Synthesis of 4,4′-((4-methoxy-3-(trifluoromethyl)phenyl)methylene)diphenol 20

Compound prepared from 19 following General Procedures Condensation on 4.9 mmol scale. 20 was afforded as a pale red solid (1.7 g; 93%).

### Synthesis of 4,4′-((4-methoxy-3-(trifluoromethyl)phenyl)methylene)bis(2,6-diiodophenol) 21

Compound 21 was prepared from 20 following General Procedures Iodination—Method I on 2.14 mmol scale. 21 was afforded as a orange/red solid (0.77 g; 41% yield).

### Synthesis of 4,4′-((4-hydroxy-3-(trifluoromethyl)phenyl)methylene)bis(2,6-diiodophenol) 22

Compound 22 was prepared from 21 following General Procedures Dealkylation on 0.88 mmol scale. 22 was afforded as a orange solid (0.32 g; 42

### Synthesis of 2,2′-(((((4-(oxiran-2-ylmethoxy)-3-(trifluoromethyl)phenyl)methylene)bis(2,6-diiodo-4,1-phenylene))bis(oxy))bis(methylene))bis(oxirane) CL 2103

This compound was prepared from 22 following General Procedures Epoxide Appendage on 0.37 mmol scale. CL 2103 was afforded as a white solid (0.17 g; 51%).

### Synthesis of Compound 16

### Synthesis of 4,4′,4″,4′″-(1,4-phenylenebis(methanetriyl))tetraphenol 25

Compound prepared from terephthalaldehyde following General Procedures Condensation on 7.46 mmol scale. Phenol was used at 9 molar equivalents. ZnCh and PTSA were used at 0.2 molar equivalents. 25 was afforded as a white solid (1.7 g; 48%).

### 1,4-bis(bis(4-(oxiran-2-ylm ethoxy)phenyl)methyl)benzene

Compound 16 was prepared from 25 following General Procedures Epoxide Appendage on 1.54 mmol scale. Epichlorohydrin was used at 100 molar equivalents and Et4NI was used at 0.4 molar equivalents.

### Synthesis of Compound 14

### Synthesis of 4,4′,4″,4′″-((perfluoro-1,4-phenylene)bis(methanetriyl))tetraphenol 26

Compound prepared from tetrafluoro-terephthalaldehyde following General Procedures Condensation on 9.7 mmol scale. Phenol was used at 9 molar equivalents. ZnCh and PTSA were used at 0.2 molar equivalents. 26 was afforded as a pale yellow solid (5.04 g; 95%)

### Synthesis of 2,2′,2″,2′″-(((((perfluoro-1,4-phenylene)bis(methanetriyl))tetrakis(benzene-4,1-diyl))tetrakis(oxy))tetrakis(methylene))tetrakis(oxirane) CL 2122

Compound 14 was prepared from 26 following General Procedures Epoxide Appendage on 4.85 mmol scale. Epichlorohydrin was used at 100 molar equivalents and Et4NI was used at 0.4 molar equivalents, afforded as a pale yellow solid (0.95 g; 25

### Synthesis of Compound 10

### Synthesis of (3-((4-(bis(4-(oxiran-2-ylmethoxy)phenyl)methyl)phenoxy)methyl)oxetan-3-yl)methanol

Under nitrogen a solution 4,4,4-trihydroxyphenylmethane (1 g; 3.42 mmol), NaH (82 mg; 3.42 mmol) in DMF (10 mL) was stirred for 5 min before (3-(bromomethyl)oxetan-3-yl)methanol (1.24 g; 6.84 mmol) was added. The reaction mixture was heated to 50° C. for 16 h. Epichlorohydrin (5 mL; 64 mmol) was added followed by Et4NI (260 mg; I mmol) and the mixture was heated to 80° C. for a further 16 h. NaOH 50% w/w in water (0.82 mL) was added to the reaction mixture with the reaction being held for a further 3 h. The reaction mixture was cooled to room temperature and filtered through cotton. The mixture was washed with EtOAc (2×10 mL) followed by water (15 mL). The organic phase was washed with brine (15 mL) and dried over MgSO4. The organic phase was evaporated to dryness under reduced pressure. The solid was further purified by column chromatography (silica; 90% dichloromethane: 10% ethyl acetate.

### Synthesis of Compound 15

### Synthesis of 4,4′-((4-methoxy-2-(trifluoromethyl)phenyl)methylene)diphenol 27

Compound prepared from 4-methoxy-2-(trifluoromethyl)benzaldehyde following General Procedures Condensation on 4.9 mmol scale. 27 was afforded as a white solid (1.7 g; 93

### Synthesis of 4,4′-((4-hydroxy-2-(trifluoromethyl)phenyl)methylene)diphenol 28

Compound 28 was prepared from 27 following General Procedures Dealkylation on 4.8 mmol scale. 28 was afforded as a white solid (1.1 g; 63

### Synthesis of 2,2′-(((((4-(oxiran-2-ylmethoxy)-2-(trifluoromethyl)phenyl)methylene)bis(4,1-phenylene))bis(oxy))bis(methylene))bis(oxirane)

Compound 15 was prepared from 28 following General Procedures Epoxide Appendage on 3.05 mmol scale. CL 2128 was afforded as a colourless solid (0.7 g; 44%).

### Synthesis of Compound 22

### Synthesis of 4,4′-((2-hydroxy-3,5-diiodophenyl)methylene)bis(2,6-diiodophenol) 32

Adapted from a literature procedure.^{I} KI (4.70 g, 28.32 mmol) was added portion-wise to a solution of 4,4′-((2-hydroxyphenyl)methylene)diphenol 13 (synthesis shown in Scheme 7, 1.38 g, 4.72 mmol), NaIO4 (6.06 g, 28.32 mmol) and NaCl (3.31 g, 56.65 mmol) in AcOH/water (9:1, v/v, 16 ml). The resulting mixture was stirred at room temperature until full consumption of the starting material was observed on TLC. Water was added (30 ml) and the mixture extracted with EtOAc (3×25 ml). The combined organic fractions were washed with brine (35 ml), dried over anhydrous magnesium sulphate, filtered, and concentrated under reduced pressure. The obtained crude residue was purified by automated flash column chromatography (0-50% Hx/EtOAc). The title compound was obtained as a dark red solid in 9% yield (0.430 g, 0.41 mmol).

### Synthesis of 2,2′-{{{{{3,5-diiodo-2-{oxiran-2-ylmethoxy)phenyl)methylene)bis{2,6-diiodo-4,1-phenylene))bis{oxy))bis{methylene))bis{oxirane) Compound 22

Compound prepared from 4,4′-((2-hydroxy-3,5-diiodophenyl)methylene)bis(2,6-diiodophenol) 32, following the General Procedures Epoxide Appendage on a 0.41 mmol scale. The title compound was obtained as clear, viscous oil in 40% yield (0.200 g, 0.16 mmol).
1. C. Ge, H. Wang, B. Zhang, J. Yao, X. Li, W. Feng, P. Zhou, Y. Wang and J. Fang, Chem. Commun., 2015, 51, 14913-14916.
2. K. Omura, J Org. Chem., 1984, 49, 3046-3050.
3. A A Kelkar, N. M. Patil and R. V. Chaudhari, Tetrahedron Lett., 2002, 43, 7143-7146.
4. T. Dohi, N. Yamaoka and Y. Kita, Tetrahedron, 2010, 66, 5775-5785.

### Formulations

General formulation: The formulations are described in molar ratios as each of the novel crosslinkers have different molecular weights. The crosslinkers with high opacity crosslinkers (Compounds 1-7 and 9-15) are formulated at a different molar equivalency (Formula B, below) than the non-high opacity crosslinkers (Compounds 8 and 16), (Formula A1-A2, below).
Formula A1: Into ethyl lactate is added 1 molar eq. of the novel crosslinker, 0.461 molar equivalent of the PAG, and 0.090 molar eq. of a nucleophilic quencher. to make a 16.5 g/L.
Formula A2: Into ethyl lactate is added 0.128 molar eq. of EX2, 1 molar eq. of the novel crosslinker, 0.461 molar equivalent of the PAG, and 0.090 molar eq. of a nucleophilic quencher. to make a 16.5 g/L.
Formula B1: Into ethyl lactate are added 1 molar eq. of the novel crosslinker, 0.455 molar equivalent of the PAG, and 0.077 molar eq. of a nucleophilic quencher.
Formula B2: Into ethyl lactate are added 0.063 molar eq. of EX2, 1 molar eq. of the novel crosslinker, 0.455 molar equivalent of the PAG, and 0.077 molar eq. of a nucleophilic quencher.

It was also found that the 2 or more crosslinkers, including different isomers of the current disclosure could be combined in various proportions to obtain a combination to form a blend of properties of those blended crosslinkers.

The percent solids in the formulation may be altered to obtain a film thickness of 20 nm when spun and dried.

### Testing of Formulations

Note: The formulations are prepared at such concentration to obtain a 20 nm film thickness when spun at 1500-2500 rpm and dried. The film thicknesses are measured using ellipsometry optical techniques.

A silicon wafer was spin coated at 2000 rpm using Brewer Science Optistack AL 212 underlayer and baked at 205° C. for 30 sec. The resist formulation was dispensed using a pipette onto the wafer and spun at the spin speed required to get a 20 nm film thickness target, generally 1200-2300 rpm. The wafer was baked at 60 C for 3 minutes and checked that the film is still appropriate for exposure (e.g. no dewetting).

The wafer was exposed using a non-contact mask using the PSI synchrotron, the mask contains patterns at pitch 44 nm line spaces and a number of die are exposed on one wafer with increasing dosages. The wafers may optionally be subjected to a post exposure bake for 1-2 minutes, generally at 60°-SO° C. The wafer was immersion developed in nBA (n-butyl acetate) for 30-60 seconds and then, optionally, have a 15 second rinse in MIBC (methyl isobutyl carbinol).

The patterns were then inspected using a SEM and images were taken through dose. The line widths and line width roughness were measured using a software package called SMILE.

The line widths and LWR were plotted against dose, trendlines are calculated, and the dose required to achieve 22 nm lines is calculated from this plot; and the LWR at 22 nm lines is also recorded.

### Results

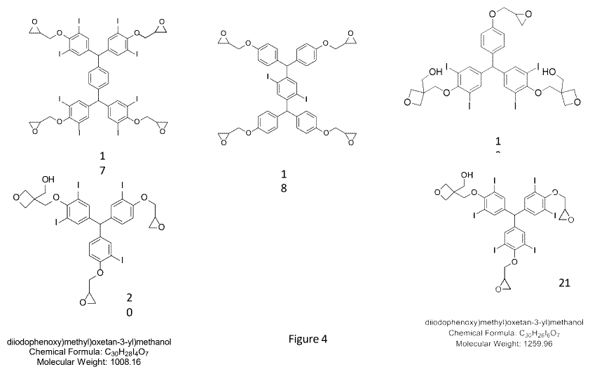

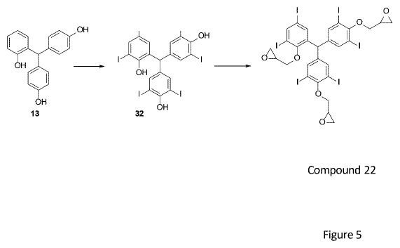

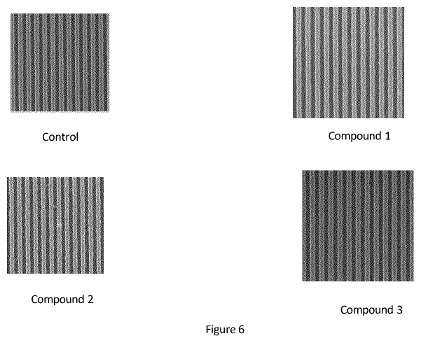

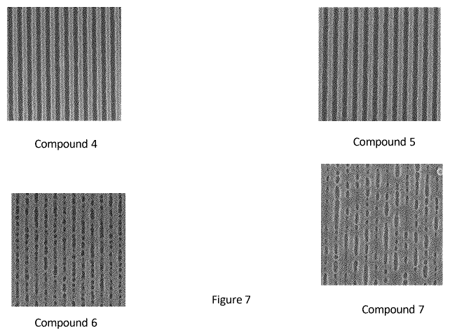

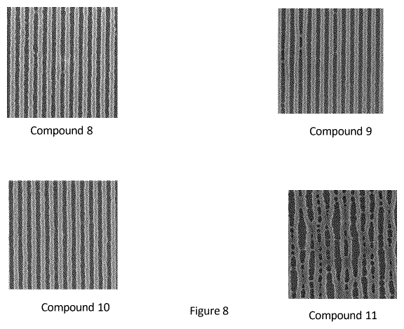

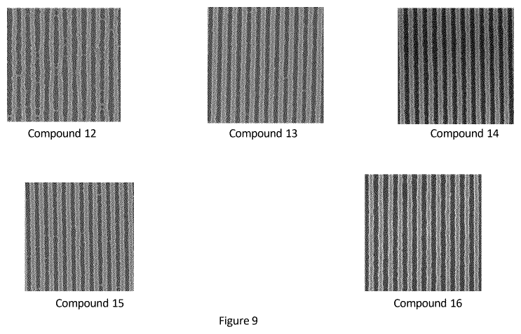

FIGS. 4-8 show Scanning Electron Microscope images of the formulation using the designated novel crosslinker of the current disclosure.
Note: In some SEMs for example the SEM for Compounds 6 and 7 do not have acceptable resist structure, but the photospeed was very high and perhaps a lower dose could make the pattern more acceptable.

The results show that a variety of very specific acid sensitive epoxy and oxetane crosslinkers exhibit major improvements in line width roughness or photospeed or both when used in EUV photoresists compared to commercial or other classes of oxygen containing crosslinkers. Also of note is the improvement in results as they relate to the crosslinkers that contain the highly EUV absorbance iodide substituents at various positions throughout the molecule, as well as fluoride substituents and combinations thereof.

### Line Width Roughness Improvements

As can be seen from Table I below, Compound 1, when compared to the commercial control, the addition of a methylene group between the oxygen functionality of the phenol moiety and the epoxy functionality improves the line width roughness by 30%.

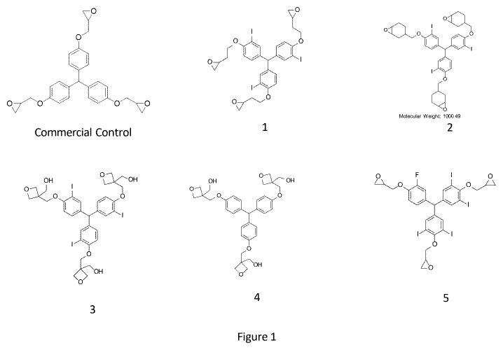

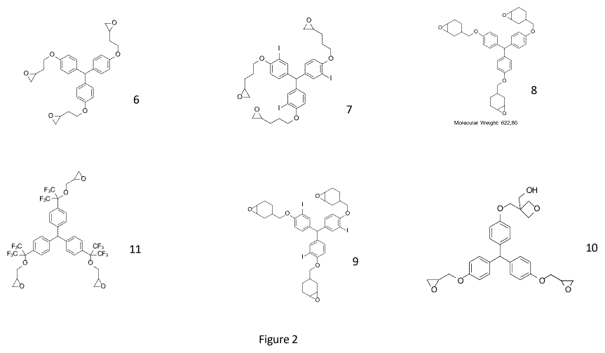

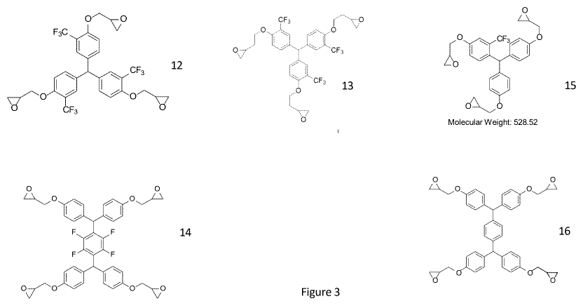

TABLE I

| | Compound (See FIG. 1, 4) | | | | | | |
|---|---|---|---|---|---|---|---|
| | Commercial | | | | | | |
| | Control | 1 | 2 | 3 | 4 | 5 | 20 |
| Line | 4.54 | 3.07 | 4.19 | 3.45 | 3.74 | 3.85 | 2.74 |
| Width | | (−30%) | (−7.7%) | (−21%) | (−18%) | (−15%) | (−39.6%) |
| Rouglmess | | | | | | | |
| (nm) | | | | | | | |

Also in Table 1, Compound 2 shows a 7.7% improvement in line width roughness when the epoxy group is situated on a cyclohexane structure. Also in Table 1, when substituting an oxetane group for the epoxy (Compounds 3 and 4) an improvement in line width roughness is obtained, 21% and 18% respectively. In Table 1, Compound 5 has the core of Compound 1 but had both Iodides and fluoride substituted on the phenyl rings, giving an improvement of 15% in line width roughness.

### Photospeed Enhancement

When formulated into an EUV photoresist the crosslinking compounds of Tables 2, 3 and 4 provided improvements in photospeed when compared to commercially available crosslinkers. Not to be held to theory, it is believed that the added degree of freedom provided by extending the reactive epoxy or oxetane group farther away from the core structure, as in Compounds 1 and 2, provides for easier access for crosslinking. Interestingly it was surprisingly found that the oxetane group of Compound 3 provided an increase in photospeed but not as large as compounds 1 or 2. It is believed that the epoxy groups have more strain than an oxetane thus being more reactive.

Compound 1 and 6 different in that Compound contained 3 iodides substituted on the aromatic rings. Surprisingly the non-iodized compound showed very high speed. Compound 7, which differed from the control and Compound 6 in that the epoxy chain contained another methylene group, thus moving the reactive epoxy even farther away from the core molecule also showed very high photospeed.

TABLE 2

| | Compound | | | | | |
|---|---|---|---|---|---|---|
| | Commercial | | | | | |
| | Control | 1 | 2 | 3 | 6 | 7 |
| Photospeed | 42.4 | 29.5 | 30.7 | 34.4 | <24 | <24 |
| (mJ) | | 30% | 27.6% | 18.9% | <43.4% | <43.4% |

Other variations of the novel crosslinker presented in the current disclosure are shown in Table 3 and Table 4 below:

As shown in Table 3, Compounds 8, 9 and 2 are all members of the epoxy cyclohexane crosslinking functional group. As can be seen, the photospeed is enhanced compared to the commercial control, but they have essentially equal photospeeds despite the alterations in the molecule or the blending of isomers. Compound 10 has 2 epoxy groups pendent on the molecule and 1 oxetane. The photospeed is essentially the same as the all-epoxy molecule and is essentially the same I photospeed, i.e., much improved over the commercial control.

Compound 11 contains 6 trifluoromethyl groups substituted on the methylene group alpha to the phenol oxygen. Here again the photospeed is much improved over the commercial crosslinker.

TABLE 3

| Compound | Commercial Control | 8 | 9 | 10 | 11 |
|---|---|---|---|---|---|
| Photospeed | 42.4 | 30.9 | 27.5 | 34.9 | 36.8 |
| (mJ) | | 27.1% | 35.1% | 17.7% | 13.2% |

Table 4 discloses other novel crosslinkers of the current application. Compound 12 shows a member of the fluorinated molecules of the disclosure. Here 3 trifluoromethyl groups are substituted onto the phenyl ring. The photospeed was better than the control but not as fast as some of the other novel crosslinkers presented. While the photospeed did not increase as high as some of the other crosslinkers presented here, the presence of fluorinated groups presents other advantages such as solubility.

Compound 13 is similar to Compound 12 but with an extra methylene group alpha to the phenol oxygen, thus extending the ether chain and moving the reactive epoxy group farther from the core molecule. As can be seen the photospeed is vastly enhanced by extending the chain, by a factor of about 7. Compound 15 is similar to Compound 12 but with only 1 trifluoromethyl group substituted on the phenyl group. The photospeed increases compared to the triple substituted crosslinker.

Compounds 14 and 16 contain the penta-aryl basic core construction (Structure II): 1,4-Bis-(diphenylmethyl) benzene. The epoxy groups are glycidyl ethers while Compound 14 contains 4 fluorides substituted on the central phenyl ring. As can be seen the photospeed of Compound 14 is greatly enhanced while the non-fluorinated Compound 16 shows only slight improvement in photospeed.

| | Compound | | | | | |
|---|---|---|---|---|---|---|
| | Commercial | | | | | |
| | Control | 12 | 13 | 14 | 15 | 16 |
| Photo- | 42.4 | 40.8 | 30.5 | 27.2 | 36.2 | 39 |
| speed | | | | | | |
| (mJ) | | 3.8% | 28.1% | 35.9% | 14.7% | 8.1% |

We claim:

1. Acid or base sensitive crosslinkers comprising a core tris(4-hydroxyphenyl)methane group having the structure I: 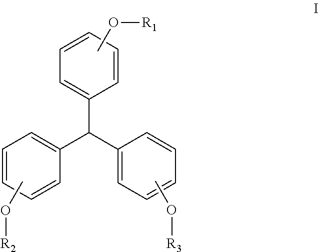
wherein RI-R3 are the same or different and are comprised of at least one epoxy-ether crosslinking functionalities, cycloepoxy-ether crosslinking functionalities and/or oxetane-ether crosslinking functionalities.

2. The crosslinkers of claim 1, wherein RI-R3 are the same or different comprising at least one of glycidyl ethers, 1,2-epoxy 4-butyl ethers, 1,2-epoxy cyclohexane-4-methyl ethers or oxetane ether groups.

3. Acid or base sensitive crosslinkers comprising a core tris(4-hydroxyphenyl)methane group having the structure: 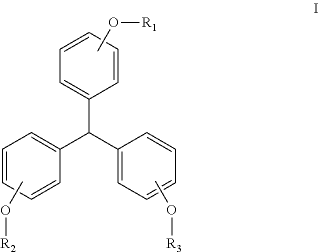
wherein RI-R3 are the same or different and are comprised of at least one of epoxy-ether crosslinking functionalities, cycloepoxy-ether crosslinking functionalities and/or oxetane-ether crosslinking functionalities and wherein at least one of the hydrogens on at least one of the hydroxyphenyl groups are substituted with iodide, fluoride or fluoride-containing groups, or combinations thereof.

4. The crosslinkers of claim 3, wherein RI-R3 are the same or different comprising at least one of glycidyl ethers, I,2-epoxy 4-butyl ethers, I,2-epoxy cyclohexane-4-methyl ethers or oxetane ether groups.

5. Acid or base sensitive crosslinkers comprising a core I,4-(bis-4′-hydroxydiphenylmethyl) benzene core having the structure II: 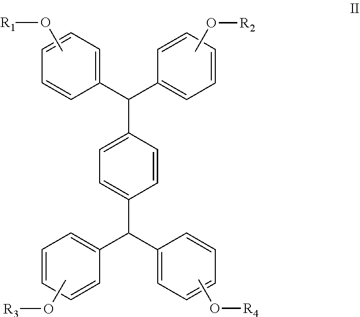
wherein RI-R4 are the same or different and are comprised of at least one epoxy-ether crosslinking functionalities, cycloepoxy-ether crosslinking functionalities and/or oxetane-ether crosslinking functionalities.

6. The crosslinkers of claim 5, wherein RI-R4 are the same or different comprising glycidyl ethers, I,2-epoxy 4-butyl ethers, I,2-epoxy cyclohexane-4-methyl ethers or oxetane ether groups.

7. Acid or base sensitive crosslinkers comprising a core tris(4-hydroxyphenyl)methane group having the structure II: 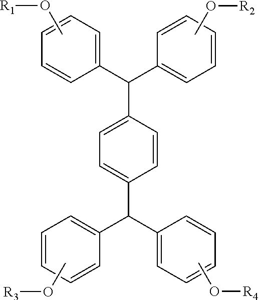
wherein RI-R3 are the same or different and are comprised of epoxy-ether crosslinking functionalities, cycloepoxy-ether crosslinking functionalities and/or oxetane-ether crosslinking functionalities and wherein at least one of the hydrogens on at least one of the hydroxyphenyl groups are substituted with iodides, fluorides or fluoride-containing groups, or combinations thereof.

8. The crosslinkers of claim 7, wherein RI-R4 are the same or different comprising glycidyl ethers, 1,2-epoxy 4-butyl ethers, 1,2-epoxy cyclohexane-4-methyl ethers or oxetane ether groups.

9. Photosensitive compositions comprising:
a. at least one epoxy ether having a structure chosen from I or II below: 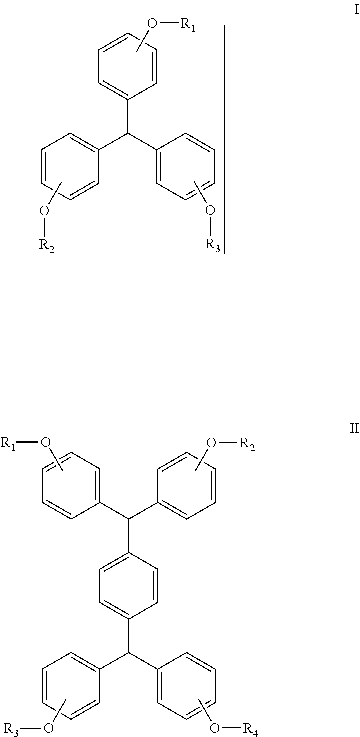
b. At least one photoacid or photobase generator; and
c. At least one solvent.
wherein R1-R4 are the same or different comprising epoxy-ether crosslinking functionalities cycloepoxy-ether crosslinking functionalities and/or oxetane-ether crosslinking functionalities.

10. The compositions of claim 9, wherein R1-R4 are the same or different comprising glycidyl ethers, 1,2-epoxy 4-butyl ethers, 1,2-epoxy cyclohexane-4-methyl ethers or oxetane ether groups.

11. The compositions of claim 9, wherein R1-R4 are the same or different comprising of epoxy-ether crosslinking functionalities, cycloepoxy-ether crosslinking functionalities and/or oxetane-ether crosslinking functionalities and wherein at least one of the hydrogens on at least one of the hydroxyphenyl groups are substituted with iodides, fluorides or fluoride-containing groups, or combinations thereof.

12. The compositions of claim 9, further comprising a nucleophilic quencher.

13. The compositions of claim 11, wherein the nucleophilic quencher is triphenylsulphonium triflate or triphenylsulphonium tosylate.

14. The compositions of claim, wherein the at least one solvent comprises an ester, ethyl lactate, an ether, an ether-ester, propylene glycol monomethyl ether acetate, propylene glycol monomethyl ether,

15. Photosensitive compositions of claim 9, further comprising at least of a zwitterionic component; wherein R1-R4 are the same or different comprising epoxy-ether crosslinking functionalities cycloepoxy-ether crosslinking functionalities and/or oxetane-ether crosslinking functionalities.

16. The compositions of claim 14, wherein RI-R4 are the same or different comprising of epoxy-ether crosslinking functionalities, cycloepoxy-ether crosslinking functionalities and/or oxetane-ether crosslinking functionalities and wherein at least one of the hydrogens on at least one of the hydroxyphenyl groups are substituted with iodides, fluorides or fluoride-containing groups, or combinations thereof.
